(19) United States
(12) Patent Application Publication
(10) Pub. No.: US 2026/0299062 A1
(43) Pub. Date: Oct. 1, 2026

(54) MAGNETIC RESONANCE IMAGING APPARATUS

(71) Applicant: CANON MEDICAL SYSTEMS CORPORATION, Otawara-shi (JP)

(72) Inventors: Michiru KAJIWARA, Nasushiobara Tochigi (JP); Sadanori TOMIHA, Nasushiobara Tochigi (JP); Takehiro SHIBUYA, Nasushiobara Tochigi (JP)

(73) Assignee: CANON MEDICAL SYSTEMS CORPORATION, Otawara-shi (JP)

(21) Appl. No.: 19/558,736

(22) Filed: Mar. 6, 2026

(30) Foreign Application Priority Data
Mar. 31, 2025 (JP) 2025-058392

(51) Int. Cl. G01R 33/36; G01R 33/54

(52) U.S. Cl. CPC G01R 33/3607; G01R 33/543

(57) ABSTRACT

A waveform outputter outputs a control waveform of a RF pulse. An adjuster adjusts a phase and/or an amplitude of the control waveform. A signal generator generates a control signal of the adjusted control waveform. A selector includes two or more pieces of frequency selector corresponding to two or more passbands. The two or more pieces of frequency selector output two or more frequency component signals corresponding to the two or more passbands based on the control signal. A coil unit includes an RF coil group including two or more RF coils having two or more different resonance frequencies. The RF coil group emits a wideband RF pulse upon receiving the two or more frequency component signals. The adjuster adjusts a phase and/or an amplitude of the control waveform based on a first circuitry characteristic of the RF coil group and a second circuitry characteristic of frequency selection circuitry.

### CROSS-REFERENCE TO RELATED APPLICATIONS

This application is based upon and claims the benefit of priority from Japanese Patent Application No. 2025-058392, filed Mar. 31, 2025, the entire contents of which are incorporated herein by reference.

### FIELD

Embodiments described herein relate generally to a magnetic resonance imaging apparatus.

### BACKGROUND

A static magnetic field magnet is designed, by way of example, such that a radius of a field of view (FOV) is 50 cm. Thus, while the homogeneity of a magnetic field is high inside the radius of 50 cm, the homogeneity of the magnetic field rapidly decreases outside the radius of 50 cm. In order to include a region outside the radius of 50 cm in the FOV, it is necessary to perform excitation using a radiofrequency (RF) pulse even in a region with an inhomogeneous magnetic field. To excite a region with an inhomogeneous magnetic field, it is desirable to emit, with high accuracy as designed, an RF pulse capable of sweeping a wide range of frequencies.

### BRIEF DESCRIPTION OF THE DRAWINGS

FIG. 1 is a diagram illustrating a configuration example of a magnetic resonance imaging apparatus according to the present embodiment;

FIG. 2 is a diagram illustrating an example of a static magnetic field distribution in a bore;

FIG. 3 is a diagram illustrating an example of a frequency characteristic of a radiofrequency (RF) coil whose resonance frequency ω0 is adjusted to a single frequency;

FIG. 4 is a diagram illustrating a configuration example of a transmission system of an RF pulse according to the present embodiment;

FIG. 5 is a diagram illustrating a specific configuration and processing example of the transmission system of the RF pulse according to the present embodiment;

FIG. 6 is a diagram schematically illustrating adjustment processing of a control waveform;

FIG. 7 is a diagram illustrating an example of a first circuitry characteristic of RF coils;

FIG. 8 is a diagram illustrating an example of a second circuitry characteristic of a high-pass filter and a low-pass filter;

FIG. 9 is a diagram illustrating an example of circuitry characteristic determination and measurement processing executed by sequence control circuitry;

FIG. 10 is a diagram schematically illustrating circuitry characteristic determination processing executed in a case where the number of RF coils is two and the number of frequency filters is two; and

FIG. 11 is a diagram schematically illustrating circuitry characteristic determination processing executed in a case where the number of RF coils is three and the number of frequency filters is three.

### DETAILED DESCRIPTION

A magnetic resonance imaging apparatus according to an embodiment includes a waveform output unit, an adjustment unit, a signal generation unit, a selection unit, and a coil unit. The waveform output unit outputs a control waveform of a wideband radiofrequency (RF) pulse. The adjustment unit adjusts a phase and/or an amplitude of the control waveform and outputs an adjusted control waveform. The signal generation unit generates a control signal of the adjusted control waveform. The selection unit includes two or more pieces of frequency selection circuitry corresponding to two or more passbands, and the two or more pieces of frequency selection circuitry output two or more frequency component signals corresponding to the two or more passbands based on the control signal. The coil unit includes a single RF coil having two or more different resonance frequencies or an RF coil group including two or more RF coils having two or more different resonance frequencies, and the single RF coil or the RF coil group emits the wideband RF pulse upon receiving the two or more frequency component signals. The adjustment unit adjusts a phase and/or an amplitude of the control waveform based on a first circuitry characteristic of the single RF coil or the RF coil group and a second circuitry characteristic of the two or more pieces of frequency selection circuitry.

Various Embodiments will be described hereinafter with reference to the accompanying drawings.

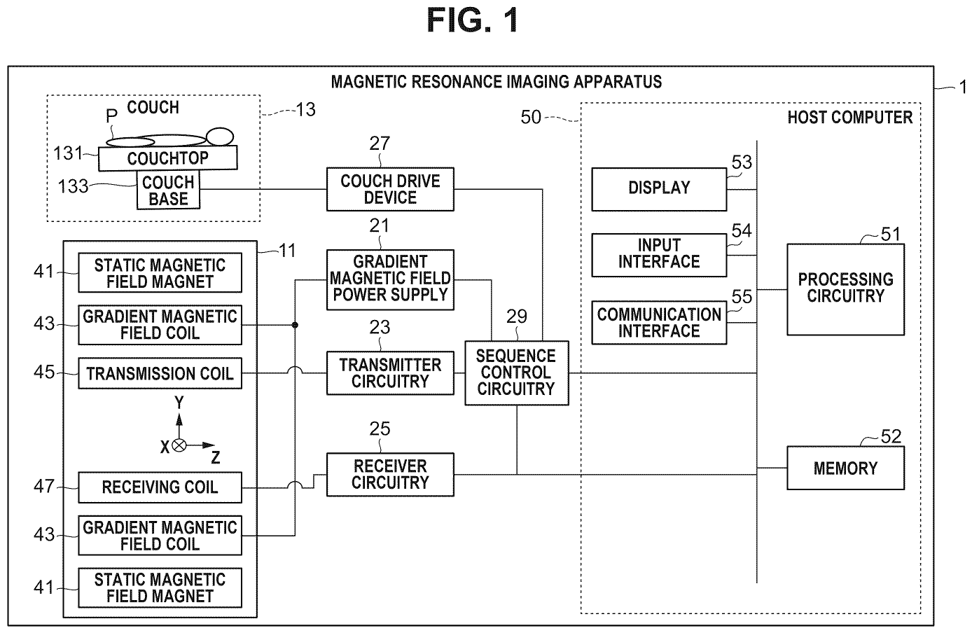

FIG. 1 is a diagram illustrating a configuration example of a magnetic resonance imaging apparatus 1 according to the present embodiment. As illustrated in FIG. 1, the magnetic resonance imaging apparatus 1 includes a gantry 11, a couch 13, a gradient magnetic field power supply 21, transmitter circuitry 23, receiver circuitry 25, a couch drive device 27, sequence control circuitry 29, and a host computer 50.

The gantry 11 includes a static magnetic field magnet 41 and a gradient magnetic field coil 43. The static magnetic field magnet 41 and the gradient magnetic field coil 43 are accommodated in a gantry housing having a cylindrical shape. In the gantry housing, a hollow space (hereinafter, bore) having a columnar shape is formed. In the bore of the gantry 11, a transmission coil 45 and a receiving coil 47 are disposed.

The static magnetic field magnet 41 has a hollow substantially-cylindrical shape and generates a static magnetic field inside a substantially cylindrical interior. Here, a central axis of the static magnetic field magnet 41 is defined as a Z-axis, an axis vertically orthogonal to the Z-axis is defined as a Y-axis, and an axis horizontally orthogonal to the Z-axis is defined as an X-axis. The X-axis, the Y-axis, and the Z-axis constitute an orthogonal three-dimensional coordinate system.

The gradient magnetic field coil 43 is a coil unit that is attached to an inner side of the static magnetic field magnet 41 and is formed into a hollow substantially-cylindrical shape. The gradient magnetic field coil 43 generates a gradient magnetic field upon receiving supply of a current from the gradient magnetic field power supply 21. More specifically, the gradient magnetic field coil 43 includes three coils corresponding to the X-axis, the Y-axis, and the Z-axis orthogonal to each other. The three coils form gradient magnetic fields whose magnetic field strength varies along the respective axes of the X-axis, the Y-axis, and the Z-axis. The gradient magnetic fields along the X-axis, the Y-axis, and the Z-axis are combined to form a slice selection gradient magnetic field Gs, a phase encoding gradient magnetic field Gp, and a frequency encoding gradient magnetic field Gr that are orthogonal to each other in desired directions. The slice selection gradient magnetic field Gs is used to freely determine an imaging plane (slice). The phase encoding gradient magnetic field Gp is used to vary a phase of a magnetic resonance signal (hereinafter referred to as an MR signal) in accordance with a spatial position. The frequency encoding gradient magnetic field Gr is used to vary a frequency of an MR signal in accordance with a spatial position. In the following description, a gradient direction of the slice selection gradient magnetic field Gs is assumed to correspond to the Z-axis, a gradient direction of the phase encoding gradient magnetic field Gp is assumed to correspond to the Y-axis, and a gradient direction of the frequency encoding gradient magnetic field Gr is assumed to correspond to the X-axis.

The gradient magnetic field power supply 21 supplies a current to the gradient magnetic field coil 43 in accordance with a sequence control signal from the sequence control circuitry 29. By supplying the current to the gradient magnetic field coil 43, the gradient magnetic field power supply 21 causes the gradient magnetic field coil 43 to generate the gradient magnetic fields along the respective axes of the X-axis, the Y-axis, and the Z-axis. The gradient magnetic fields are superimposed on the static magnetic field formed by the static magnetic field magnet 41 and are applied to a subject P.

The transmission coil 45 is disposed, for example, inside the gradient magnetic field coil 43, and generates a high-frequency pulse (hereinafter referred to as a radiofrequency (RF) pulse) upon receiving a supply of a current from the transmitter circuitry 23.

The transmitter circuitry 23 supplies a current to the transmission coil 45 to emit an RF pulse for exciting a target proton present in the subject P, to the subject P via the transmission coil 45. The RF pulse vibrates at a resonant frequency unique to the target proton, and excites the target proton. An MR signal is generated from the excited target proton, which is detected by the receiving coil 47. The transmission coil 45 is, for example, a whole body coil (WB coil). The whole body coil may be used as a transmit/receive coil.

Under the influence of an RF magnetic-field pulse, the receiving coil 47 receives an MR signal emitted from the target proton present in the subject P. The receiving coil 47 includes a plurality of receiving coil elements that can receive MR signals. The received MR signal is supplied to the receiver circuitry 25 via a wired or wireless connection. Although not illustrated in FIG. 1, the receiving coil 47 includes a plurality of reception channels implemented in parallel. Each reception channel includes a receiving coil element that receives an MR signal, an amplifier that amplifies the MR signal, and the like. The MR signal is output for each reception channel. The total number of reception channels may be equal to the total number of receiving coil elements, may be greater than the total number of receiving coil elements, or may be smaller than the total number of receiving coil elements.

The receiver circuitry 25 receives an MR signal generated from an excited target proton, via the receiving coil 47. The receiver circuitry 25 generates a digital MR signal by performing signal processing on the received MR signal. The digital MR signal can be represented in k-space defined by spatial frequency. Accordingly, hereinafter, the digital MR signal will be referred to as k-space data. The k-space data is a type of raw data supplied for image reconstruction. The k-space data is supplied to the host computer 50 via a wired or wireless connection.

The transmission coil 45 and the receiving coil 47 described above are merely examples. A transmit/receive coil having a transmission function and a reception function may be used in place of the transmission coil 45 and the receiving coil 47. In addition, the transmission coil 45, the receiving coil 47, and the transmit/receive coil may be combined.

The couch 13 is disposed adjacent to the gantry 11. The couch 13 includes a couchtop 131 and a couch base 133. The subject P is placed on the couchtop 131. The couch base 133 supports the couchtop 131 so as to be slidable along each of the X-axis, the Y-axis, and the Z-axis. The couch drive device 27 is accommodated in the couch base 133. The couch drive device 27 moves the couchtop 131 by receiving control from the sequence control circuitry 29. The couch drive device 27 may include, for example, any motor such as a servomotor or a stepping motor, or the like.

The sequence control circuitry 29 includes, as hardware resources, a processor such as a central processing unit (CPU) or a microprocessing unit (MPU), and a memory such as a read only memory (ROM) or a random access memory (RAM). The sequence control circuitry 29 synchronously controls the gradient magnetic field power supply 21, the transmitter circuitry 23, and the receiver circuitry 25 based on an image capturing condition set by processing circuitry 51, executes MR image capturing of the subject P in accordance with a pulse sequence corresponding to the image capturing condition, and collects k-space data regarding the subject P.

As illustrated in FIG. 1, the host computer 50 is a computer including the processing circuitry 51, a memory 52, a display 53, an input interface 54, and a communication interface 55.

The processing circuitry 51 includes, as a hardware resource, a processor such as a CPU. The processing circuitry 51 functions as a core of the magnetic resonance imaging apparatus 1. For example, the processing circuitry 51 automatically or manually sets an image capturing condition. In addition, the processing circuitry 51 reconstructs an MR image regarding the subject P based on k-space data collected via the receiver circuitry 25. In addition, the processing circuitry 51 can also perform various types of processing such as rendering processing, image recognition, and image analysis on the MR image.

The memory 52 is a storage device such as a hard disk drive (HDD), a solid state drive (SSD), or an integrated circuit storage device that stores various types of information. In addition, the memory 52 may be a drive device or the like that reads and writes various types of information from and into a portable storage medium such as a compact disc read only memory (CD-ROM) drive, a digital versatile disc (DVD) drive, or a flash memory. For example, the memory 52 stores an image capturing condition, k-space data, an MR image, a control program, and the like.

The display 53 displays various types of information. For example, the display 53 displays an MR image, an image capturing condition setting screen, and the like. As the display 53, for example, a cathode-ray tube (CRT) display, a liquid crystal display, an organic electroluminescence (EL) display, a light-emitting diode (LED) display, a plasma display, or any other display known in the technical field may be used as appropriate.

The input interface 54 includes an input device that receives various commands from an operator. As the input device, a keyboard, a mouse, various switches, a touch screen, a touch pad, and the like can be used. The input device is not limited to an input device including a physical operating component such as a mouse or a keyboard. For example, electric signal processing circuitry that receives an electric signal corresponding to an input operation from an external input device provided separately from the magnetic resonance imaging apparatus 1, and outputs the received electric signal to various types of circuitry is also included in the examples of the input interface 54. In addition, the input interface 54 may be a voice recognition device that converts a voice signal collected by a microphone into an instruction signal.

The communication interface 55 is an interface that connects the magnetic resonance imaging apparatus 1 to a workstation, a picture archiving and communication system (PACS), a hospital information system (HIS), a radiology information system (RIS), and the like via a local area network (LAN) or the like. A network interface (IF) transmits and receives various types of information to and from the connected workstation, PACS, HIS, or RIS.

The above-described configuration is an example, and the configuration is not limited thereto. For example, the sequence control circuitry 29 may be incorporated into the host computer 50. The sequence control circuitry 29 and the processing circuitry 51 may be mounted on the same substrate.

Here, the static magnetic field inhomogeneity assumed in the present embodiment will be described.

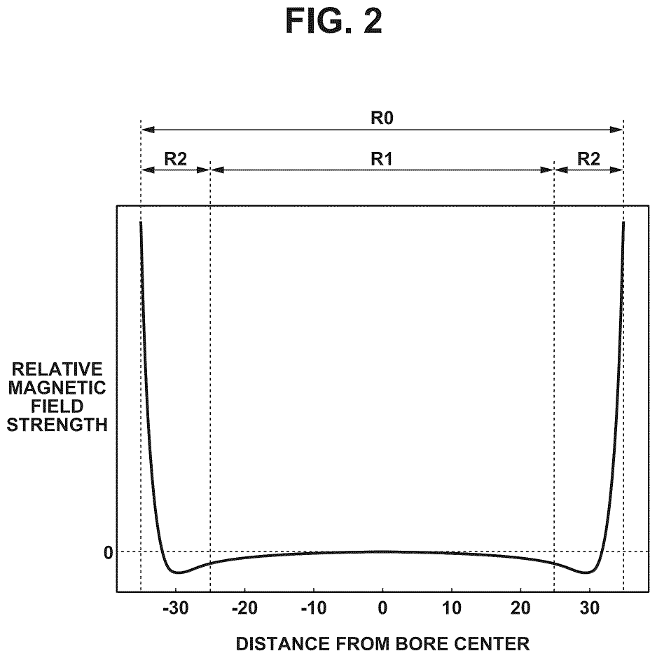

FIG. 2 is a diagram illustrating an example of a static magnetic field distribution in the bore. In FIG. 2, a horizontal axis is defined as a distance, in centimeters (cm), in a radial direction from a central axis (the Z-axis) of the bore, and a vertical axis is defined as a relative magnetic field strength, in parts per million (ppm). Specifically, the vertical axis represents a relative magnetic field strength when the magnetic field strength on the central axis of the bore is set to 0. The static magnetic field distribution illustrated in FIG. 2 represents a transverse cross-section including an arbitrary point on the central axis; however, the position of the arbitrary point is not particularly limited. In a columnar region R1 having a diameter of 50 (−25 to +25) cm, a magnetic field strength is spatially substantially homogeneous. In a cylindrical region R2 located 10 cm (−25 to −35 and +25 to +35) cm outward from the region R1, a magnetic field strength is spatially inhomogeneous. In the present embodiment, an attempt is made to utilize the region R2, which has conventionally been considered as unsuitable for an image capturing region (hereinafter, a field of view (FOV)) because a magnetic field strength is inhomogeneous, as the FOV. In other words, the FOV according to the present embodiment is assumed to be a combined region R0 of the columnar region R1 and the cylindrical region R2.

For magnetic resonance imaging, it is necessary to spatially homogeneously excite nuclear spins of target nuclei present within the FOV using an RF pulse emitted from an RF coil included in the transmission coil 45. The resonance frequency of the RF coil is adjusted to a certain single frequency, and the RF coil emits an RF pulse having a center frequency corresponding to the resonance frequency. Such a property dependent on the frequency of the RF coil is referred to as a frequency characteristic.

Because a resonance frequency of a nuclear spin depends on a magnetic field strength at a position where the nuclear spin is present, when a static magnetic field in a FOV is inhomogeneous, the resonance frequency of the nuclear spin varies greatly depending on the position. To excite a region where the magnetic field is inhomogeneous, it is desirable to accurately emit, as designed, an RF pulse that can sweep over a wide range of frequencies. Therefore, an RF coil having a favorable frequency characteristic over a wide range of frequencies is desired.

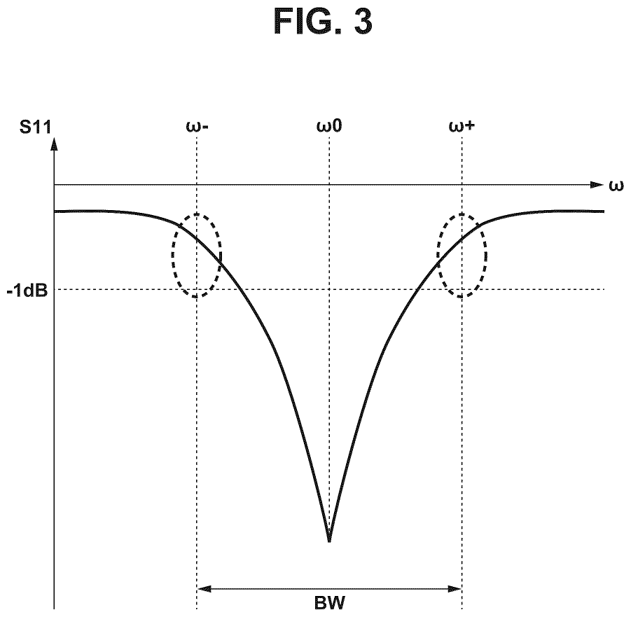

FIG. 3 is a diagram illustrating an example of a frequency characteristic of an RF coil whose resonance frequency ω0 is adjusted to a single frequency. In FIG. 3, a vertical axis is defined as a S11 parameter that is a reflection coefficient, and a horizontal axis is defined as a frequency ω. The reflection coefficient is an example of an index representing the frequency characteristic of an RF coil, and indicates that transmission sensitivity of the RF coil is higher as an absolute value in a negative direction becomes larger. Hereinafter, it is defined that a large absolute value of a negative value of the reflection coefficient corresponds to a small reflection coefficient, and a small absolute value of a negative value of the reflection coefficient corresponds to a large reflection coefficient. In the present embodiment, it is assumed that a condition for use as an RF coil is that a reflection coefficient is equal to or smaller than −1 decibel (dB).

As described above, the resonance frequency ω0 of the RF coil is adjusted to a single frequency. At the resonance frequency ω0, the reflection coefficient has a minimum value; however, as the frequency deviates from the resonance frequency ω0, the reflection coefficient increases. A predetermined width centered on the resonance frequency ω0 is set as a bandwidth BW (ω− to ω+) of the RF pulse. The reflection coefficient within the bandwidth BW is desirably equal to or smaller than −1 dB; however, as illustrated in FIG. 3, in the vicinity of a boundary of the bandwidth BW such as ω− and ω+, the reflection coefficient is larger than −1 dB.

In this manner, while the RF coil exhibits a favorable frequency characteristic in the vicinity of the resonance frequency, the RF coil does not exhibit an intended frequency characteristic in a frequency band separated from the resonance frequency to some extent. Accordingly, in an RF coil whose resonance frequency is adjusted to a single frequency, it is difficult to homogeneously perform excitation within an FOV in which a magnetic field is inhomogeneous, and a transmission efficiency of the RF coil and an excitation efficiency of nuclear spins are poor.

The magnetic resonance imaging apparatus according to the present embodiment efficiently transmits an RF pulse using a single RF coil having two or more resonance frequencies, or an RF coil group including two or more RF coils having two or more resonance frequencies.

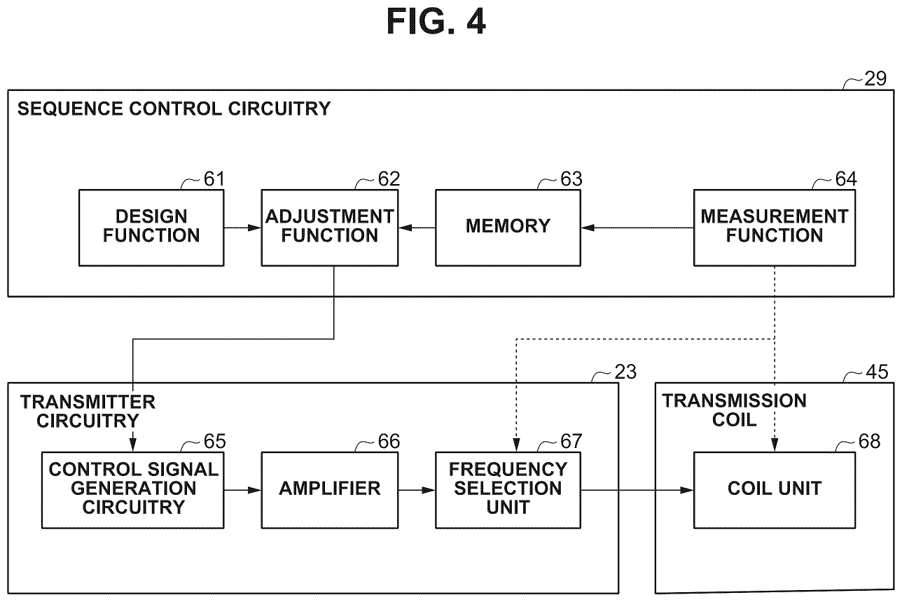

FIG. 4 is a diagram illustrating a configuration example of a transmission system of an RF pulse according to the present embodiment. As illustrated in FIG. 4, the sequence control circuitry 29, the transmitter circuitry 23, and the transmission coil 45 are provided as components related to the transmission system. The sequence control circuitry 29 executes a design function 61, an adjustment function 62, and a measurement function 64. In addition, the sequence control circuitry 29 includes a memory 63.

By implementation of the design function 61, the sequence control circuitry 29 outputs a control waveform of a wideband RF pulse. The “wideband” according to the present embodiment means that a frequency band that can be excited is wider than a frequency band that can be excited by an RF pulse emitted by an RF coil adjusted to a single resonance frequency. The control waveform is assumed to be digital data. The design function 61 is an example of a waveform output unit.

By implementation of the adjustment function 62, the sequence control circuitry 29 outputs an adjusted control waveform by adjusting a phase and/or an amplitude of the control waveform output by the design function 61. More specifically, the sequence control circuitry 29 adjusts the phase and/or the amplitude of the control waveform based on a first circuitry characteristic of a single RF coil or an RF coil group included in a coil unit 68, and a second circuitry characteristic of a plurality of pieces of frequency selection circuitry included in a frequency selection unit 67. The adjusted control waveform is assumed to be digital data. The adjustment function 62 is an example of an adjustment unit.

In the case of adjusting the amplitude of the control waveform, based on the first circuitry characteristic and the second circuitry characteristic, the sequence control circuitry 29 estimates an attenuation amount of the control waveform in the single RF coil or the RF coil group, and two or more pieces of frequency selection circuitry. Then, based on the estimated attenuation amount, the sequence control circuitry 29 adjusts the amplitude of the control waveform such that a waveform of a wideband RF pulse emitted from the coil unit 68 becomes similar to a control waveform output from the design function 61. In the case of adjusting the phase of the control waveform, based on the first circuitry characteristic and the second circuitry characteristic, the sequence control circuitry 29 estimates a change amount of the phase of the control waveform in the single RF coil or the RF coil group, and two or more pieces of frequency selection circuitry. Then, based on the estimated change amount of the phase, the sequence control circuitry 29 adjusts the phase of the control waveform such that a phase of the waveform of the wideband RF pulse emitted from the coil unit 68 matches the phase of the control waveform output from the design function 61.

The memory 63 stores data of the first circuitry characteristic of the single RF coil or the RF coil group included in the coil unit 68, and data of the second circuitry characteristic of the two or more pieces of frequency selection circuitry included in the frequency selection unit 67. The data of the first circuitry characteristic and the data of the second circuitry characteristic are used for an adjustment of the control waveform that is to be performed by the adjustment function 62. The memory 63 is an example of a storage unit.

By implementation of the measurement function 64, the sequence control circuitry 29 measures the first circuitry characteristic of the single RF coil or the RF coil group included in the coil unit 68, and the second circuitry characteristic of the plurality of pieces of frequency selection circuitry included in the frequency selection unit 67. Data of the measured first circuitry characteristic and data of the measured second circuitry characteristic are stored in the memory 63. A timing of circuitry characteristic measurement to be executed by the measurement function 64 is not particularly limited, and the characteristics may be measured at the time of installation, may be measured after the adjustment of a circuit constant, or may be measured at another arbitrary timing. The measurement function 64 is an example of a measurement unit.

As illustrated in FIG. 4, the transmitter circuitry 23 includes a control signal generation circuitry 65, an amplifier 66, and the frequency selection unit 67. The control signal generation circuitry 65 generates a control signal of an adjusted control waveform output by the adjustment function 62. The control signal is assumed to be an analog electric signal. The control signal generation circuitry 65 is an example of a signal generation unit.

The amplifier 66 amplifies the power of a control signal output from the control signal generation circuitry 65 and outputs a transmitted RF signal. As the amplifier 66, for example, a power amplifier (PA) is used. The amplifier 66 is an example of an amplification unit.

The frequency selection unit 67 includes two or more pieces of frequency selection circuitry corresponding to two or more passbands. The two or more pieces of frequency selection circuitry output two or more frequency component signals corresponding to the two or more passbands based on the transmitted RF signal output from the amplifier 66. More specifically, a single piece of frequency selection circuitry corresponds to one passband, and a signal (frequency component signal) corresponding to the one passband among transmitted RF signals is output from the single piece of frequency selection circuitry. In other words, the frequency component signal is a signal having a frequency corresponding to a passband as a center frequency. As the frequency selection circuitry, a frequency filter that extracts or removes a specific frequency component is used. The two or more pieces of frequency selection circuitry correspond to, for example, resonance circuitry including a coil and a capacitor, and are desirably formed as high-voltage-tolerant analog circuitry. The frequency selection unit 67 is an example of a selection unit.

As illustrated in FIG. 4, the transmission coil 45 includes the coil unit 68. The coil unit 68 includes a single RF coil having two or more different resonance frequencies, or an RF coil group including two or more RF coils having two or more different resonance frequencies. The single RF coil or the RF coil group emits a wideband RF pulse upon receiving two or more frequency component signals. The single RF coil or the RF coil group receives two or more frequency component signals and emits two or more RF pulses, and a superimposed waveform of the two or more RF pulses becomes similar to a control waveform of a wideband RF pulse output by the design function 61. The single RF coil or the RF coil group is configured such that a circuitry parameter thereof is adjusted such that a reflection coefficient of the single RF coil or the RF coil group becomes equal to or less than −1 dB within a bandwidth of a wideband RF pulse based on a reference frequency. For example, a whole body coil may be used as the RF coil.

Hereinafter, a structure and an operation of the transmission system of the RF pulse according to the present embodiment will be specifically described. In the following embodiment, the coil unit 68 is assumed to be an RF coil group including two RF coils having two different resonance frequencies. In this case, the frequency selection unit 67 includes two pieces of frequency selection circuitry corresponding to the two RF coils.

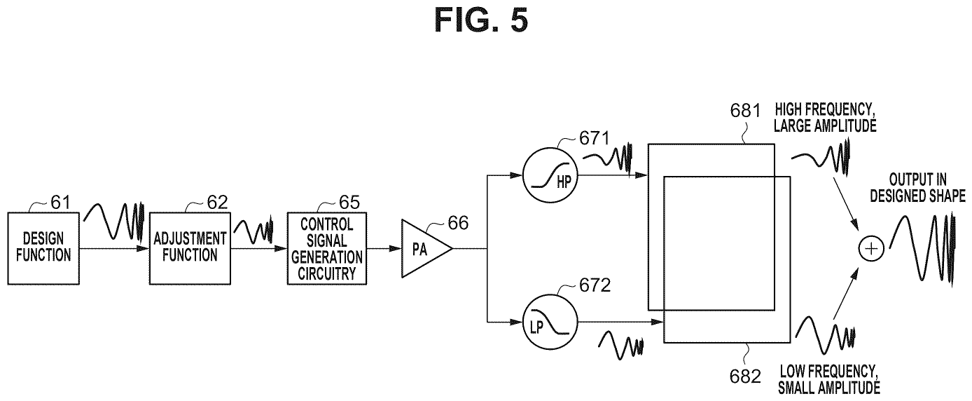

FIG. 5 is a diagram illustrating a specific configuration and processing example of the transmission system of the RF pulse according to the present embodiment. As illustrated in FIG. 5, a control waveform of a wideband RF pulse is output by the design function 61 of the sequence control circuitry 29, the control waveform is adjusted by the adjustment function 62 of the sequence control circuitry 29, a control signal of the adjusted control waveform is generated by the control signal generation circuitry 65, the power of the control signal is amplified by the amplifier 66 (PA), and output as the transmitted RF signal. The transmitted RF signal is distributed to a high-pass filter 671 (HP) and a low-pass filter 672 (LP). The high-pass filter 671 extracts a high-frequency component signal from the transmitted RF signal, and the low-pass filter 672 extracts a low-frequency component signal from the transmitted RF signal. The high-frequency component signal is supplied to a first RF coil 681, and a first RF pulse corresponding to the high-frequency component signal is generated from the first RF coil 681. The low-frequency component signal is supplied to a second RF coil 682, and a second RF pulse corresponding to the low-frequency component signal is generated from the second RF coil 682. A superimposed waveform of the first RF pulse and the second RF pulse becomes similar to the control waveform designed by the design function 61.

Hereinafter, the details will be described. First, by use of the design function 61, the sequence control circuitry 29 designs a control waveform of a wideband RF pulse that is expected to be emitted from the coil unit 68. Here, the sequence control circuitry 29 calculates a band of a resonance frequency based on a maximum magnetic field strength and a minimum magnetic field strength in a distribution of a magnetic field to be applied to an image capturing region, and sets the calculated band of the resonance frequency as a band of a wideband RF pulse. Specifically, a band having a predetermined width centered on the resonance frequency is set as the band of the wideband RF pulse. As the distribution of the magnetic field to be applied to the image capturing region, a distribution of a static magnetic field to be applied by the static magnetic field magnet 41 may be used, or a distribution of a superimposed magnetic field of the static magnetic field to be applied by the static magnetic field magnet 41 and a gradient magnetic field to be applied by the gradient magnetic field coil 43 may be used. The distribution of the magnetic field may be measured, or may be calculated based on image capturing conditions such as a strength of the static magnetic field and a pulse sequence.

A control waveform may be designed by the design function 61 for each combination of static magnetic field strength, gradient magnetic field strength, transmit magnetic field strength, and the like. The wideband RF pulse is used as an excitation pulse or a refocusing pulse in a pulse sequence. As one example, the wideband RF pulse may be a pulse intended for wideband excitation, such as a chirped pulse or a wideband, uniform rate, smooth truncation (WURST) pulse. As another example, the wideband RF pulse may be a simultaneous multiple slice excitation pulse such as a simultaneous multi-slice (SMS) pulse.

By use of the adjustment function 62, the sequence control circuitry 29 adjusts the phase and/or the amplitude of a control waveform output by the design function 61, based on the first circuitry characteristic of the RF coils 681 and 682 included in the coil unit 68 and the second circuitry characteristic of the high-pass filter 671 and the low-pass filter 672 included in the frequency selection unit 67.

In the case of adjusting the amplitude, based on the first circuitry characteristic and the second circuitry characteristic, the adjustment function 62 estimates an attenuation amount of the control waveform in the RF coils 681 and 682 included in the coil unit 68 and in the high-pass filter 671 and the low-pass filter 672 included in the frequency selection unit 67. Then, based on the estimated attenuation amount, the sequence control circuitry 29 adjusts the amplitude of the control waveform such that a waveform of a wideband RF pulse emitted from the RF coils 681 and 682 becomes similar to the control waveform output from the design function 61.

In the case of adjusting the phase, based on the first circuitry characteristic and the second circuitry characteristic, the adjustment function 62 estimates a change amount of a phase of the control waveform in the RF coils 681 and 682 included in the coil unit 68 and in the high-pass filter 671 and the low-pass filter 672 included in the frequency selection unit 67. Then, based on the estimated change amount of the phase, the sequence control circuitry 29 adjusts the phase of the control waveform such that the phase of a waveform of a wideband RF pulse emitted from the RF coils 681 and 682 matches the phase of the control waveform output from the design function 61.

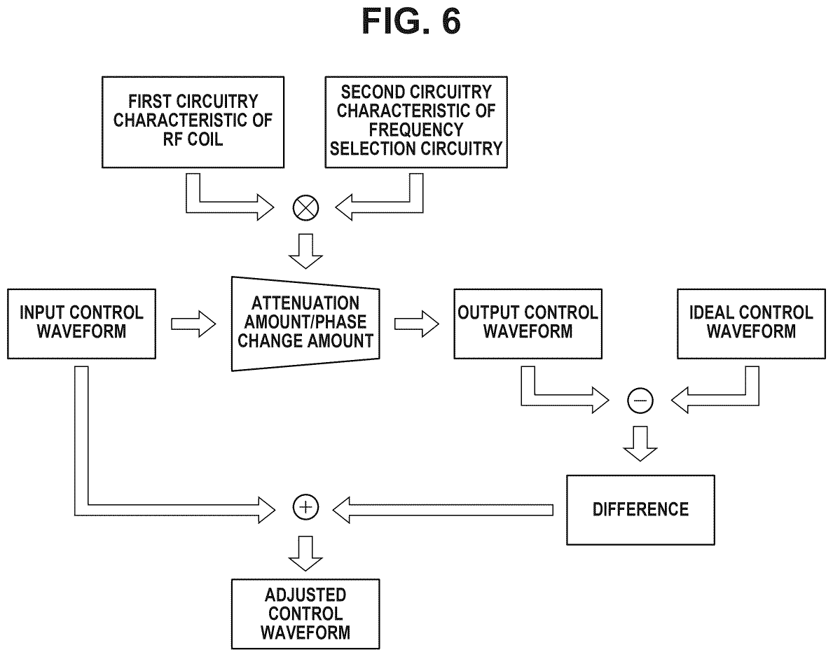

FIG. 6 is a diagram schematically illustrating adjustment processing of a control waveform. As illustrated in FIG. 6, the first circuitry characteristic of the RF coils 681 and 682 and the second circuitry characteristic of the high-pass filter 671 and the low-pass filter 672 are acquired. As one example, the sequence control circuitry 29 reads out the data of the first circuitry characteristic and the data of the second circuitry characteristic that have been preliminarily measured by the measurement function 64 and stored in the memory 63, and adjusts the phase and/or the amplitude of the control waveform based on the read data of the first circuitry characteristic and the read data of the second circuitry characteristic. As another example, the sequence control circuitry 29 may measure the first circuitry characteristic of the RF coils 681 and 682 and the second circuitry characteristic of the high-pass filter 671 and the low-pass filter 672 each time the adjustment processing is performed, and may adjust the phase and/or the amplitude of the control waveform based on the measured first and second circuitry characteristics.

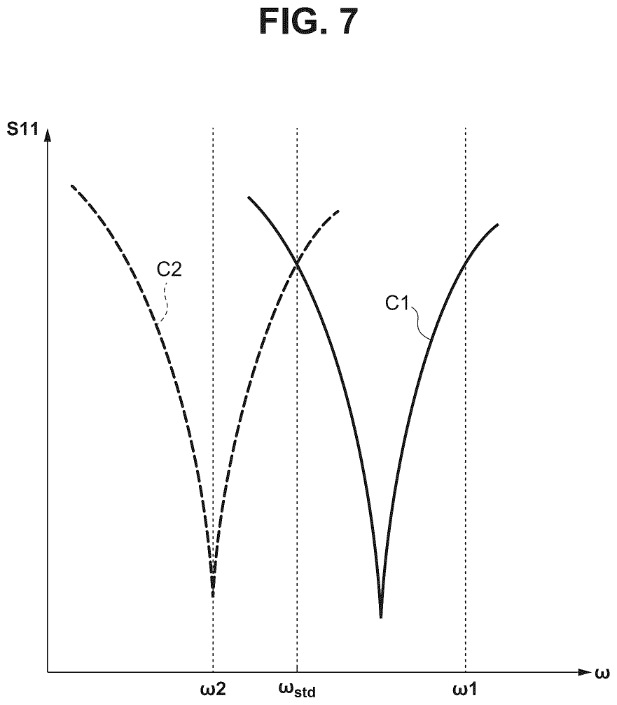

FIG. 7 is a diagram illustrating an example of the first circuitry characteristic of the RF coils 681 and 682. In FIG. 7, a vertical axis is defined by a reflection coefficient (S11 parameter), and a horizontal axis is defined by frequency. A curve C1 represents a frequency change of a reflection coefficient regarding the first RF coil 681, and a curve C2 represents a frequency change of a reflection coefficient regarding the second RF coil 682. The frequency change of the reflection coefficient is an example of a circuitry characteristic. Regarding the curve C1, the reflection coefficient is a minimum value at a center frequency ω1, and the reflection coefficient increases as the frequency moves away from the center frequency ω1. A shape of the curve C1 is unique to the first RF coil 681. When a control signal flows through the first RF coil 681, an amplitude and/or a phase of the control signal is disturbed in accordance with a circuitry characteristic corresponding to the curve C1. The same applies to the curve C2. A sum of the curves C1 and C2 represents a circuitry characteristic of the coil unit 68 including the RF coils 681 and 682. The amplitude and/or the phase of the control signal is disturbed in accordance with the circuitry characteristic of the coil unit 68.

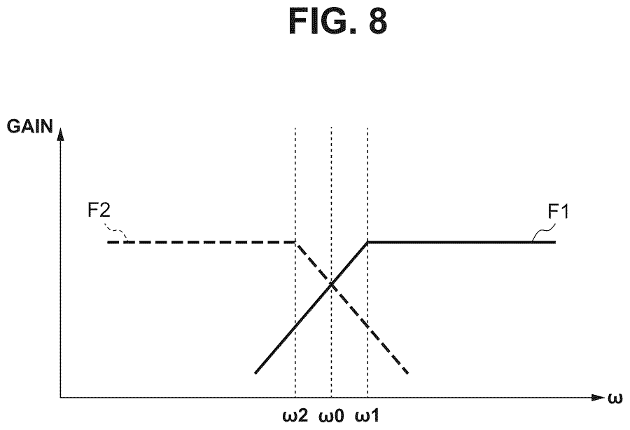

FIG. 8 is a diagram illustrating an example of the second circuitry characteristic of the high-pass filter 671 and the low-pass filter 672. In FIG. 8, a vertical axis is defined by a gain, and a horizontal axis is defined by frequency. A line F1 represents a frequency change of a gain regarding the high-pass filter 671, and a line F2 represents a frequency change of a gain regarding the low-pass filter 672. As indicated by the line F1, regarding the high-pass filter 671, a band of frequencies equal to or higher than a frequency ω1, which is higher than a cutoff frequency ω0, is set as a passband. As indicated by the line F2, regarding the low-pass filter 672, a band of frequencies equal to or lower than a frequency ω2, which is lower than the cutoff frequency ω0, is set as a passband. When a control signal flows through the high-pass filter 671, an amplitude and/or a phase of the control signal is disturbed in accordance with a circuitry characteristic corresponding to the line F1. A sum of the lines F1 and F2 represents a circuitry characteristic related to the amplitude of the frequency selection unit 67 including the high-pass filter 671 and the low-pass filter 672. The amplitude and/or the phase of the control signal is disturbed in accordance with the circuitry characteristic of the frequency selection unit 67.

As illustrated in FIG. 6, the sequence control circuitry 29 estimates an attenuation amount and a phase change amount of the control signal based on the first circuitry characteristic and the second circuitry characteristic. The attenuation amount means a degree of attenuation of signal strength for each frequency of the control signal that is caused when the control signal flows through the frequency selection unit 67 and the coil unit 68. The attenuation amount is estimated based on the first circuitry characteristic and the second circuitry characteristic that represent a frequency change of a reflection coefficient such as the S11 parameter. The phase change amount means a degree of a phase shift for each frequency of the control signal that is caused when the control signal flows through the frequency selection unit 67 and the coil unit 68. The phase change amount is estimated based on the first circuitry characteristic and the second circuitry characteristic that represent a frequency change of a phase change.

When the attenuation amount and the phase change amount are estimated, the sequence control circuitry 29 applies the attenuation amount and the phase change amount to a control waveform (input control waveform) output from the design function 61, and generates an output control waveform. The output control waveform represents a control waveform after the output waveform from the design function 61 is subjected to the attenuation and the phase change caused by the frequency selection unit 67 and the coil unit 68.

Next, the sequence control circuitry 29 calculates a difference between the output control waveform and an ideal control waveform. The calculated difference represents a difference between the ideal control waveform and a control waveform after being subjected to attenuation and a phase change caused by the frequency selection unit 67 and the coil unit 68. The ideal control waveform is a waveform that an RF pulse emitted from the coil unit 68 is expected to have, and is set, for example, to a control waveform designed by the design function 61. The sequence control circuitry 29 generates an adjusted control waveform by applying the calculated difference to the control waveform. In the case of performing an adjustment based on an attenuation amount, the sequence control circuitry 29 increases a signal strength of the control waveform by an amount (difference) that compensates for the estimated attenuation amount. As an example, in a case where an attenuation amount at 40 MHz is −10 dB, the signal strength of the control waveform at 40 MHz is increased tenfold. In the case of performing an adjustment based on a phase change amount, the sequence control circuitry 29 changes the phase of the control waveform by an amount (difference) that compensates for the estimated phase change amount. As an example, in a case where an attenuation amount at 40 MHz is −10 φ, the phase of the control waveform at 40 MHz is advanced by +10 φ. By adjusting the control waveform in accordance with the difference in this manner, an adjusted control waveform is generated. It is expected that, when the adjusted control waveform is subjected to attenuation and a phase change caused by the frequency selection unit 67 and the coil unit 68, the adjusted control waveform is changed into the ideal control waveform.

Then, as illustrated in FIG. 5, a control signal of the adjusted control waveform is generated by the control signal generation circuitry 65, the power of the control signal is amplified by the amplifier 66 (PA), and output as the transmitted RF signal. The transmitted RF signal is distributed to the high-pass filter 671 (HP) and the low-pass filter 672 (LP). The transmitted RF signal passes through the high-pass filter 671 and the low-pass filter 672, whereby a high-frequency component signal and a low-frequency component signal are extracted. By providing the frequency (high-pass/low-pass) filters 671 and 672 upstream of the RF coils 681 and 682, it is possible to change a frequency characteristic of a control signal to be supplied to the RF coils 681 and 682 into a frequency characteristic optimal for the RF coils 681 and 682 being a supply destination.

A waveform of the high-frequency component signal is subjected to amplitude attenuation and a phase change in accordance with the circuitry characteristic of the high-pass filter 671, and a waveform of the low-frequency component signal is subjected to amplitude attenuation and a phase change in accordance with the circuitry characteristic of the low-pass filter 672. The high-frequency component signal is supplied to the first RF coil 681, and the first RF pulse corresponding to the high-frequency component signal is generated from the first RF coil 681. A waveform of the first RF pulse is subjected to amplitude attenuation and a phase change in accordance with the circuitry characteristic of the first RF coil 681, and a waveform of the second RF pulse is subjected to amplitude attenuation and a phase change in accordance with the circuitry characteristic of the second RF coil 682. A waveform of a superimposed pulse of the first RF pulse and the second RF pulse becomes similar to the control waveform designed by the design function 61.

As illustrated in FIG. 5, only one amplifier 66 is provided upstream of the high-pass filter 671 and the low-pass filter 672. With this configuration, compared with a case where an amplifier 66 is provided downstream of each of the high-pass filter 671 and the low-pass filter 672, it is possible to reduce the number of amplifiers 66 and to reduce an introduction cost of the amplifier 66.

Next, determination and measurement of a circuitry characteristic will be described.

One or more cutoff frequencies of two or more pieces of frequency selection circuitry (frequency filters) are adjusted to a frequency at one or more intersections of two or more frequency distribution waveforms of a reflection coefficient of a single RF coil or an RF coil group. Two or more pieces of frequency selection circuitry according to a first processing example described below include two pieces of frequency selection circuitry, namely, first frequency selection circuitry and second frequency selection circuitry. The first frequency selection circuitry is a high-pass filter having a band of frequencies higher than one cutoff frequency as a passband, and the second frequency selection circuitry is a low-pass filter having a band of frequencies lower than one cutoff frequency as a passband. Two or more pieces of frequency selection circuitry according to a second processing example described below include first frequency selection circuitry, second frequency selection circuitry, and third frequency selection circuitry. The first frequency selection circuitry is a high-pass filter having a band of frequencies higher than the highest cutoff frequency of two or more cutoff frequencies as a passband, the second frequency selection circuitry is a low-pass filter having a band of frequencies lower than the lowest cutoff frequency of the two or more cutoff frequencies as a passband, and the third frequency selection circuitry is a bandpass filter having a band of frequencies between the highest cutoff frequency and the lowest cutoff frequency of the two or more cutoff frequencies as a passband. The number of bandpass filters may be one, or may be two or more.

### First Processing Example

The determination and measurement of a circuitry characteristic that are executed in a case where the number of RF coils is two and the number of frequency filters is two will be described.

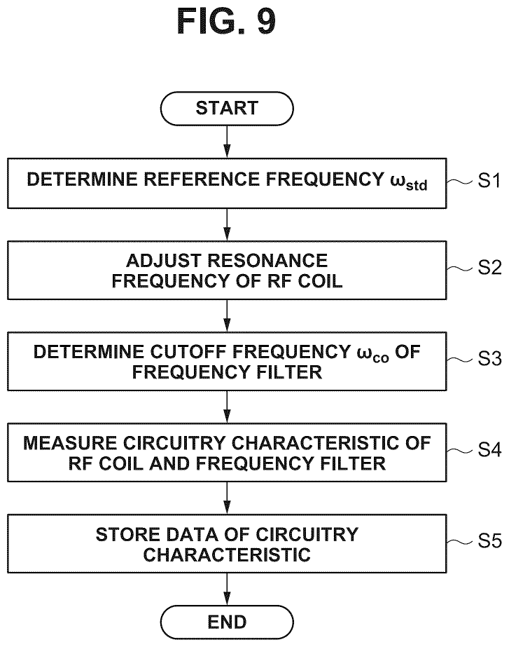

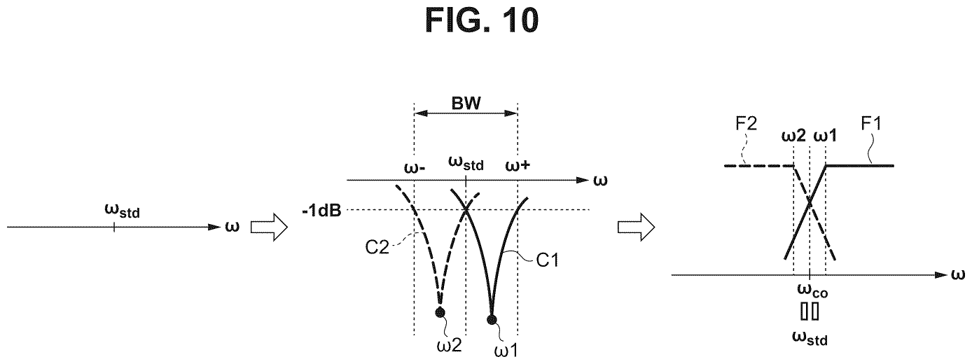

FIG. 9 is a diagram illustrating an example of circuitry characteristic determination and measurement processing executed by the sequence control circuitry 29. FIG. 10 is a diagram schematically illustrating circuitry characteristic determination processing executed in a case where the number of RF coils is two and the number of frequency filters is two. A left part of FIG. 10 illustrates a reference frequency ω_{std} on a frequency axis, a middle part of FIG. 10 illustrates a waveform C1 of a frequency characteristic regarding the first RF coil 681 and a waveform C2 of a frequency characteristic regarding the second RF coil 682, and a right part of FIG. 10 illustrates a waveform F1 of a frequency characteristic regarding the high-pass filter 671 and a waveform F2 of a frequency characteristic regarding the low-pass filter 672.

As illustrated in FIGS. 9 and 10, in step S1, the sequence control circuitry 29 determines a single reference frequency ω_{std}. The reference frequency ω_{std} corresponds to a center frequency of k-space or an MR image. As an example, the sequence control circuitry 29 may identify a maximum magnetic field strength and a minimum magnetic field strength in a distribution of a magnetic field to be applied to an image capturing region, may calculate a magnetic field strength at an approximate center between the identified maximum magnetic field strength and the minimum magnetic field strength, and may set a frequency corresponding to the calculated magnetic field strength as the reference frequency ω_{std}. As the distribution of the magnetic field to be applied to the image capturing region, a distribution of a static magnetic field to be applied by the static magnetic field magnet 41 may be used, or a distribution of a superimposed magnetic field of the static magnetic field to be applied by the static magnetic field magnet 41 and a gradient magnetic field to be applied by the gradient magnetic field coil 43 may be used. The sequence control circuitry 29 may set, as the reference frequency ω_{std}, a frequency corresponding to a magnetic field designated via the input interface 54 or a frequency designated via the input interface 54 by an operator referring to a distribution of a magnetic field displayed on the display 53 or the like.

When the processing in step S1 is performed, in step S2, the sequence control circuitry 29 adjusts a resonance frequency of the RF coils 681 and 682. Specifically, the sequence control circuitry 29 reads, from the memory 63, the data of the first circuitry characteristic regarding the RF coils 681 and 682. The data of the first circuitry characteristic is assumed to have been measured at a predetermined timing such as an installation timing.

In accordance with an instruction from an operator, circuitry parameters such as capacitance and reactance of capacitors of the RF coils 681 and 682 are adjusted such that reflection coefficients of the RF coils 681 and 682 satisfy the following conditions. Condition 1: a sum waveform of the waveforms C1 and C2 is equal to or smaller than −1 dB over an entire bandwidth BW of a wideband RF pulse. Note that the sum waveform is more desirably equal to or smaller than −3 dB. Condition 2: a resonance frequency (center frequency) ω1 of the first RF coil 681 is larger than the reference frequency ω_{std}, and a resonance frequency (center frequency) ω2 of the second RF coil 682 is smaller than the reference frequency ω_{std}. By satisfying the conditions 1 and 2, it is possible to design an RF pulse that can sweep a wideband.

When the processing in step S2 is performed, in step S3, the sequence control circuitry 29 determines a cutoff frequency ω_{co} of the frequency filters 671 and 672. Specifically, as illustrated in the right part of FIG. 10, the sequence control circuitry 29 sets the reference frequency ω_{std}, which is a frequency corresponding to an intersection of the waveform C1 of the first RF coil 681 and the waveform C2 of the second RF coil 682, as the cutoff frequency ω_{co} of the high-pass filter 671 and the low-pass filter 672. Then, the sequence control circuitry 29 sets a passband of the high-pass filter 671 to a band of frequencies higher than the cutoff frequency ω_{co}. A lower limit of the passband of the high-pass filter 671 may be set to, for example, the resonance frequency ω1 of the first RF coil 681. The sequence control circuitry 29 sets a passband of the low-pass filter 672 to a band of frequencies lower than the cutoff frequency ωco. An upper limit of the passband of the low-pass filter 672 may be set to, for example, the resonance frequency ω2 of the second RF coil 682.

When the processing in step S3 is performed, in step S4, the sequence control circuitry 29 measures circuitry characteristics of the RF coils 681 and 682 and the frequency filters 671 and 672 by use of the measurement function 64. As an example, the sequence control circuitry 29 measures, using a measuring instrument such as a network analyzer, a reflection coefficient such as the S11 parameter of the RF coils 681 and 682 and the frequency filters 671 and 672 for each frequency. By plotting measurement results of the RF coils 681 and 682 in a graph defined by a frequency and a reflection coefficient, the sequence control circuitry 29 generates data of the first circuitry characteristic that represents a frequency change of a reflection coefficient, and by plotting measurement results of the frequency filters 671 and 672, the sequence control circuitry 29 generates data of the second circuitry characteristic that represents a frequency change of a reflection coefficient. Similarly, the sequence control circuitry 29 measures, by use of a measuring instrument such as a network analyzer, an amount of phase change of a signal of the RF coils 681 and 682 and the frequency filters 671 and 672 for each frequency. By plotting measurement results of the RF coils 681 and 682 in a graph defined by a frequency and a phase, the sequence control circuitry 29 generates data of the first circuitry characteristic that represents a frequency change of a phase change, and by plotting measurement results of the frequency filters 671 and 672, the sequence control circuitry 29 generates data of the second circuitry characteristic that represents a frequency change of a phase change.

When the processing in step S4 is performed, in step S5, the sequence control circuitry 29 stores the data of the circuitry characteristics measured in step S4 in the memory 63. The circuitry characteristic of the RF coils 681 and 682 is stored as the data of the first circuitry characteristic, and the circuitry characteristic of the frequency filters 671 and 672 is stored as the data of the second circuitry characteristic. At this time, the data of the first circuitry characteristic and the data of the second circuitry characteristic may be stored in association with measurement dates and times of the respective circuitry characteristics.

When the processing in step S5 is performed, the processing according to the first processing example ends.

### Second Processing Example

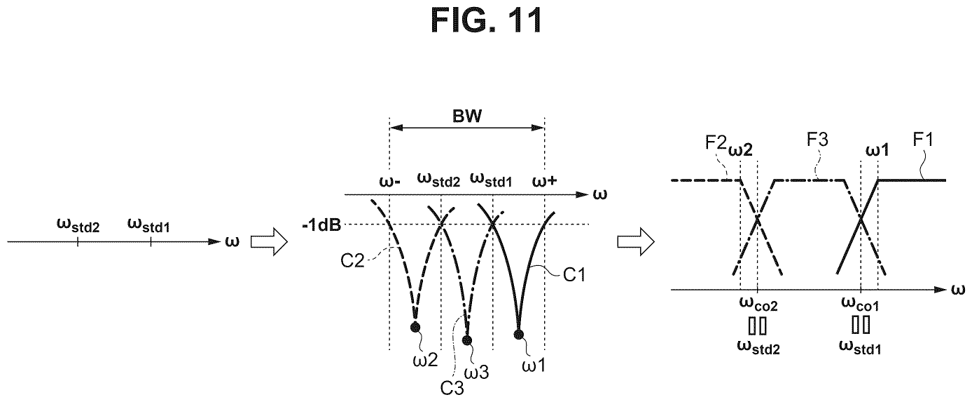

Next, circuitry characteristic determination and measurement executed in a case where the number of RF coils is three and the number of frequency filters is three will be described with reference to FIGS. 9 and 11. A flow of the circuitry characteristic determination and measurement executed in the case where the number of RF coils is three and the number of frequency filters is three is similar to that illustrated in FIG. 9. FIG. 11 is a diagram schematically illustrating circuitry characteristic determination processing executed in the case where the number of RF coils is three and the number of frequency filters is three. A left part of FIG. 11 illustrates a reference frequency ω_{std} on a frequency axis, a middle part of FIG. 11 illustrates a waveform C1 of a frequency characteristic regarding the first RF coil 681, a waveform C2 of a frequency characteristic regarding the second RF coil 682, and a waveform C3 of a frequency characteristic regarding an RF coil 683, and a right part of FIG. 11 illustrates a waveform F1 of a frequency characteristic regarding the high-pass filter 671, a waveform F2 of a frequency characteristic regarding the low-pass filter 672, and a waveform F3 of a frequency characteristic regarding a bandpass filter 673.

As illustrated in FIGS. 9 and 11, in step S1, the sequence control circuitry 29 determines two reference frequencies ω_{std1} and ω_{std2}. As an example, the sequence control circuitry 29 sets a reference frequency ω_{std} corresponding to a center frequency of k-space or an MR image, sets a frequency larger than the reference frequency ω_{std} by a predetermined amount as the reference frequency ω_{std1}, and sets a frequency smaller than the reference frequency ω_{std} by a predetermined amount as the reference frequency ω_{std2}. A method for setting the reference frequency ω_{std} is similar to that in the first processing example.

When the processing in step S1 is performed, in step S2, the sequence control circuitry 29 adjusts a resonance frequency of the RF coils 681, 682, and 683. Specifically, the sequence control circuitry 29 reads, from the memory 63, the data of the first circuitry characteristic regarding the RF coils 681, 682, and 683. The data of the first circuitry characteristic is assumed to have been measured at a predetermined timing such as an installation timing.

In accordance with an instruction from an operator, circuitry parameters such as capacitance and reactance of capacitors of the RF coils 681, 682, and 683 are adjusted such that reflection coefficients of the RF coils 681, 682, and 683 satisfy the following conditions. Condition 1: a sum waveform of the waveforms C1, C2, and C3 is equal to or smaller than −1 dB over an entire bandwidth BW of a wideband RF pulse. Note that the sum waveform is more desirably equal to or smaller than −3 dB. Condition 2: a resonance frequency (center frequency) ω1 of the first RF coil 681 is larger than the reference frequency ω_{std}, and a resonance frequency (center frequency) ω2 of the second RF coil 682 is smaller than the reference frequency ω_{std}. A resonance frequency (center frequency) ω3 of the RF coil 683 may be set between the resonance frequency ω1 and the resonance frequency ω2. By satisfying the conditions 1 and 2, it is possible to design an RF pulse that can sweep a wideband.

When the processing in step S2 is performed, in step S3, the sequence control circuitry 29 determines cutoff frequencies ω_{co1} and ω_{co2} of the frequency filters 671, 672, and 673. Specifically, as illustrated in the right part of FIG. 11, the sequence control circuitry 29 sets the reference frequency ω_{std1}, which is a frequency corresponding to an intersection of the waveform C1 of the first RF coil 681 and the waveform C3 of the RF coil 683, as the cutoff frequency ω_{co1} of the high-pass filter 671 and the bandpass filter 673. The sequence control circuitry 29 sets the reference frequency ω_{std2}, which is a frequency corresponding to an intersection of the waveform C2 of the second RF coil 682 and the waveform C3 of the RF coil 683, as the cutoff frequency ω_{co2} of the low-pass filter 672 and the bandpass filter 673.

Next, the sequence control circuitry 29 sets a passband of the high-pass filter 671 to a band of frequencies higher than the cutoff frequency ω_{co1}. A lower limit of the passband of the high-pass filter 671 may be set to, for example, the resonance frequency ω1 of the first RF coil 681. The sequence control circuitry 29 sets a passband of the bandpass filter 673 to a band of frequencies between the cutoff frequencies ωco1 and ωco2. The sequence control circuitry 29 sets a passband of the low-pass filter 672 to a band of frequencies lower than the cutoff frequency ω_{co2}. An upper limit of the passband of the low-pass filter 672 may be set to, for example, the resonance frequency ω2 of the second RF coil 682.

When the processing in step S3 is performed, in step S4, the sequence control circuitry 29 measures circuitry characteristics of the RF coils 681, 682, and 683 and the frequency filters 671, 672, and 673 by use of the measurement function 64. When the processing in step S4 is performed, in step S5, the sequence control circuitry 29 stores the data of the circuitry characteristics measured in step S4, in the memory 63. The circuitry characteristic of the RF coils 681, 682, and 683 is stored as the data of the first circuitry characteristic, and the circuitry characteristic of the frequency filters 671, 672, and 673 is stored as the data of the second circuitry characteristic. At this time, the data of the first circuitry characteristic and the data of the second circuitry characteristic may be stored in association with measurement dates and times of the respective circuitry characteristics.

When the processing in step S5 is performed, the processing according to the second processing example ends.

According to the above-described embodiment, the magnetic resonance imaging apparatus 1 includes the sequence control circuitry 29, the transmitter circuitry 23, and the transmission coil 45. The sequence control circuitry 29 includes the design function 61 that outputs a control waveform of a wideband RF pulse, and the adjustment function 62 that outputs an adjusted control waveform by adjusting the phase and/or the amplitude of the control waveform. The transmitter circuitry 23 includes the control signal generation circuitry 65 that generates a control signal of the adjusted control waveform, and the frequency selection unit 67 that is a unit including two or more pieces of frequency selection circuitry corresponding to two or more passbands, and the two or more pieces of frequency selection circuitry output two or more frequency component signals corresponding to the two or more passbands, based on the control signal. The transmission coil 45 includes the coil unit 68 that is a coil unit including a single RF coil having two or more different resonance frequencies or an RF coil group including two or more RF coils having two or more different resonance frequencies, and the single RF coil or the RF coil group emits a wideband RF pulse upon receiving the two or more frequency component signals. The adjustment function 62 adjusts the phase and/or the amplitude of the control waveform based on the first circuitry characteristic of the single RF coil or the RF coil group, and the second circuitry characteristic of the two or more pieces of frequency selection circuitry.

According to the above-described configuration, to apply an RF pulse capable of excitation in a wideband, a single RF coil or a plurality of RF coils whose resonance frequency is adjusted to two or more different frequencies is used. The two or more pieces of frequency selection circuitry are arranged immediately upstream of the single RF coil or the plurality of RF coils. By arranging frequency selection circuitry immediately upstream of RF coils, it becomes possible to emit an RF pulse in a band near the resonance frequency of each RF coil. In addition, since the phase and/or the amplitude of the control waveform are adjusted based on a circuitry characteristic related to frequency selection circuitry and RF coils through which the control signal passes, it becomes possible to accurately emit a wideband RF pulse as designed. In addition, in magnetic resonance imaging with an inhomogeneous magnetic field, when a wideband RF pulse that takes off-resonance into account is used, it is possible to perform intended excitation and improve an excitation characteristic.

The above-described embodiment is merely an example, and various additions, deletions, and/or modifications of elements can be made to the present embodiment without departing from the spirit of the application.

The magnetic resonance imaging apparatus 1 according to the above-described embodiment is a cylindrical magnetic resonance imaging apparatus including the static magnetic field magnet 41 having a cylindrical shape surrounding a hollow space having a columnar shape, the gradient magnetic field coil 43, and the gantry 11 accommodating the transmission coil 45. However, the present embodiment is not limited thereto, and is applicable to a magnetic resonance imaging apparatus in any form that can perform MR imaging in a region where homogeneity of a magnetic field is not high. As an example, a planar open-type magnetic resonance imaging apparatus including a pair of upper and lower magnet accommodation housings each having a flat-plate shape may be used. In this case, a static magnetic field magnet 41, a gradient magnetic field coil 43, and a transmission coil 45 each having a flat-plate shape are accommodated in each of the magnet accommodation housings, and an image capturing region including a magnetic field inhomogeneous region is set in a planar open space sandwiched between the pair of magnet accommodation housings. As another example, a fully open-type magnetic resonance imaging apparatus including only one of a pair of magnet accommodation housings may be used. In this case, the static magnetic field magnet 41, the gradient magnetic field coil 43, and the transmission coil 45 each having a flat-plate shape are accommodated in the magnet accommodation housing, and the image capturing region including a magnetic field inhomogeneous region is set in an open space located below or above the magnet accommodation housing.

In the magnetic resonance imaging apparatus 1 according to the above-described embodiment, as two or more RF coils having two or more different resonance frequencies, the two or more RF coils are configured such that their resonance frequencies are different from each other. However, the present embodiment is not limited thereto. For example, the magnetic resonance imaging apparatus 1 may include two or more ports having two or more resonance frequencies, and RF coils may be connected to the respective ports. The resonance frequency of an RF coil connected to one port and the resonance frequency of an RF coil connected to another port may be different from each other, or may be the same.

According to at least one embodiment described above, it is possible to accurately emit a wideband RF pulse as designed.

The term “processor” used in the above description means, for example, circuitry such as a CPU, a graphics processing unit (GPU), an application specific integrated circuit (ASIC), or a programmable logic device (PLD) (e.g., a simple programmable logic device (SPLD), a complex programmable logic device (CPLD), and a field programmable gate array (FPGA)). The processor implements functions by reading and executing a program stored in memory circuitry. Alternatively, instead of storing the program in the memory circuitry, the processor may be configured such that the program is directly incorporated in circuitry of the processor. In this case, the processor implements functions by reading and executing the program incorporated in the circuitry. On the other hand, when the processor is, for example, an ASIC, instead of storing the program in the memory circuitry, the function is directly incorporated in the circuitry of the processor as a logic circuit. Note that each processor of the present embodiment is not limited to being configured as a single piece of circuitry for each processor, and may be configured as one processor by combining a plurality of pieces of independent circuitry to implement the functions thereof. Further, a plurality of constituent elements in FIGS. 1 and 3 may be integrated into one processor to implement the functions thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic resonance imaging apparatus comprising:
processing circuitry configured to:
output a control waveform of a wideband radiofrequency (RF) pulse; and
adjust a phase and/or an amplitude of the control waveform and output an adjusted control waveform;
a signal generation unit configured to generate a control signal of the adjusted control waveform;
a selection unit configured to include two or more pieces of frequency selection circuitry corresponding to two or more passbands, the two or more pieces of frequency selection circuitry outputting two or more frequency component signals corresponding to the two or more passbands based on the control signal; and
a coil unit including a single RF coil having two or more different resonance frequencies or an RF coil group including two or more RF coils having two or more different resonance frequencies, the single RF coil or the RF coil group emitting the wideband RF pulse upon receiving the two or more frequency component signals,
wherein the processing circuitry adjusts a phase and/or an amplitude of the control waveform based on a first circuitry characteristic of the single RF coil or the RF coil group and a second circuitry characteristic of the two or more pieces of frequency selection circuitry.

2. The magnetic resonance imaging apparatus according to claim 1, wherein a circuitry parameter of the single RF coil or the RF coil group is adjusted such that a reflection coefficient of the single RF coil or the RF coil group becomes equal to or smaller than −1 dB in a bandwidth of the wideband RF pulse based on a reference frequency.

3. The magnetic resonance imaging apparatus according to claim 1, wherein one or more cutoff frequencies of the two or more pieces of frequency selection circuitry are adjusted to a frequency of one or more intersections of two or more frequency distribution waveforms of a reflection coefficient of the single RF coil or the RF coil group.

4. The magnetic resonance imaging apparatus according to claim 3,
wherein the two or more pieces of frequency selection circuitry include two pieces of frequency selection circuitry corresponding to first frequency selection circuitry and second frequency selection circuitry,
wherein the first frequency selection circuitry is a high-pass filter having a band of frequencies higher than one cutoff frequency, as a passband, and
wherein the second frequency selection circuitry is a low-pass filter having a band of frequencies lower than the one cutoff frequency, as a passband.

5. The magnetic resonance imaging apparatus according to claim 3,
wherein the two or more pieces of frequency selection circuitry include first frequency selection circuitry, second frequency selection circuitry, and third frequency selection circuitry,
wherein the first frequency selection circuitry is a high-pass filter having a band of frequencies higher than a highest cutoff frequency of two or more cutoff frequencies, as a passband,
wherein the second frequency selection circuitry is a low-pass filter having a band of frequencies lower than a lowest cutoff frequency of the two or more cutoff frequencies, as a passband, and
wherein the third frequency selection circuitry is a bandpass filter having a band of frequencies between the highest cutoff frequency and the lowest cutoff frequency of the two or more cutoff frequencies, as a passband.

6. The magnetic resonance imaging apparatus according to claim 1, wherein, based on a maximum magnetic field strength and a minimum magnetic field strength in a distribution of a magnetic field to be applied to an image capturing region, the processing circuitry calculates a band of a resonance frequency, and sets the calculated band as a band of the wideband RF pulse.

7. The magnetic resonance imaging apparatus according to claim 1, further comprising a storage unit configured to store data of the first circuitry characteristic and data of the second circuitry characteristic having been measured at an installation timing,
wherein the processing circuitry adjusts a phase and/or an amplitude of the control waveform based on the data of the first circuitry characteristic and the data of the second circuitry characteristic.

8. The magnetic resonance imaging apparatus according to claim 1,
wherein the processing circuitry measures the first circuitry characteristic and the second circuitry characteristic, and
wherein the processing circuitry adjusts a phase and/or an amplitude of the control waveform based on the measured first circuitry characteristic and the measured second circuitry characteristic.

9. The magnetic resonance imaging apparatus according to claim 1,
wherein, based on the first circuitry characteristic and the second circuitry characteristic, the processing circuitry estimates an attenuation amount of the control waveform in the single RF coil or the RF coil group and in the two or more pieces of frequency selection circuitry, and
wherein, based on the estimated attenuation amount, the processing circuitry adjusts the amplitude of the control waveform such that a waveform of the wideband RF pulse emitted from the coil unit becomes similar to the control waveform output from the processing circuitry.

10. The magnetic resonance imaging apparatus according to claim 1,
wherein, based on the first circuitry characteristic and the second circuitry characteristic, the processing circuitry estimates a change amount of a phase of the control waveform in the single RF coil or the RF coil group and in the two or more pieces of frequency selection circuitry, and
wherein, based on the estimated change amount of the phase, the processing circuitry adjusts a phase of the control waveform such that a phase of a waveform of the wideband RF pulse emitted from the coil unit matches a phase of the control waveform output from the processing circuitry.

11. The magnetic resonance imaging apparatus according to claim 1, wherein the single RF coil or the RF coil group emits two or more RF pulses upon receiving the two or more frequency component signals, and a superimposed waveform of the two or more RF pulses becomes similar to the control waveform.

12. The magnetic resonance imaging apparatus according to claim 1, further comprising an amplification unit configured to output a transmitted RF signal by amplifying power of the control signal,
wherein the two or more pieces of frequency selection circuitry extract the two or more frequency component signals from the transmitted RF signal.

13. The magnetic resonance imaging apparatus according to claim 12, wherein a number of amplification units is one.
